(19) United States
(12) Patent Application Publication
(10) Pub. No.: US 2005/0094654 A1
(43) Pub. Date: May 5, 2005

(54) Switching matrix

(76) Inventors: Oz Weisler, Zoran (IL); Eti Vandermolen, Raanana (IL); Zalma Itzhak, Zur-Moshe (IL)

Correspondence Address: Fogg and Associates, LLC, P.O. Box 581339, Minneapolis, MN, 55458-1339, US

(21) Appl. No.: 10/699,609

(22) Filed: Oct. 31, 2003

(51) Int. Cl. H03K 19/177

(52) U.S. Cl. 370/412

(57) ABSTRACT

One embodiment of a switching matrix includes a field programmable gate array having an input memory and an output memory. The field programmable gate array stores in the input memory an input frame having a plurality of input channels. The field programmable gate array stores in the output memory an output frame having a plurality of output channels is stored. The field programmable gate array further includes a map memory in which the field programmable gate array stores at least one mapping that specifies one of the plurality of input channels that is mapped to one of the output channels.

### TECHNICAL FIELD

The following description relates to telecommunications in general and to a switching matrix for a telecommunication device or system.

### BACKGROUND

A switching matrix typically receives multiple input channels and transmits each of the received input channels out on one of multiple output channels. In one embodiment, the multiple input channels are multiplexed together into input frames using time division multiplexing (TDM). In such an embodiment, each input channel occupies a particular time slot within each of the input frames. In such an embodiment, the output channels are also multiplexed together output frames using TDM. Each output channel is associated with a particular time slot within each of the output frames. The switching matrix in such an embodiment receives an input frame and generates an output frame by mapping each input channel into one of the output channels contained in the output frame. In general, the data included in such input and output channels can include any type of data traffic—for example, traditional voice telephony traffic and/or data traffic (for example, in the form of internet protocol traffic).

Typically, such a switching matrix is designed using discrete logic components or an application specific integrated circuit (ASIC). The design of such a switching matrix, however, typically cannot be changed easily. If a switching matrix is initially designed to switch 128 input channels onto 128 output channels and the requirements for such a switching matrix change so that the switching matrix must now switch 200 input channels onto 200 output channels, the switching matrix in the initial design typically must be replaced or revised to accommodate additional and/or alternative components or ASICs to support the additional channels. Such hardware redesign can be costly and/or time consuming, especially where the switching matrix is designed to handle a large number of channels (for example, thousands of channels).

### SUMMARY

In one embodiment, a switching matrix includes a field programmable gate array having an input memory and an output memory. The field programmable gate array stores in the input memory an input frame having a plurality of input channels. The field programmable gate array stores in the output memory an output frame having a plurality of output channels is stored. The field programmable gate array further includes a map memory in which the field programmable gate array stores at least one mapping that specifies one of the plurality of input channels that is mapped to one of the output channels.

In another embodiment, a switching matrix includes means for storing an input frame having a plurality of input channels, means for storing an output frame having a plurality of output channels, and means for mapping at least one of the input channels of the input frame to a corresponding one of the plurality of output channels of the output frame.

In another embodiment, a switching matrix includes an input memory, an output memory, and a field programmable gate array. The field programmable gate array stores in the input memory an input frame having a plurality of input channels and stores in the output memory an output frame having a plurality of output channels. The field programmable gate array includes a map memory in which the field programmable gate array stores at least one mapping that specifies one of the plurality of input channels that is mapped to one of the output channels.

The details of one or more embodiments of the claimed invention are set forth in the accompanying drawings and the description below. Other features and advantages will become apparent from the description, the drawings, and the claims.

### DRAWINGS

FIG. 1 is a block diagram of one embodiment of a switching matrix.

FIG. 2 is a flow diagram of one embodiment of a method of clocking an input frame into the switching matrix of FIG. 1.

FIG. 3 is a flow diagram of one embodiment of method of mapping input channels of an input frame to output channels of an output frame.

Like reference numbers and designations in the various drawings indicate like elements.

### DETAILED DESCRIPTION

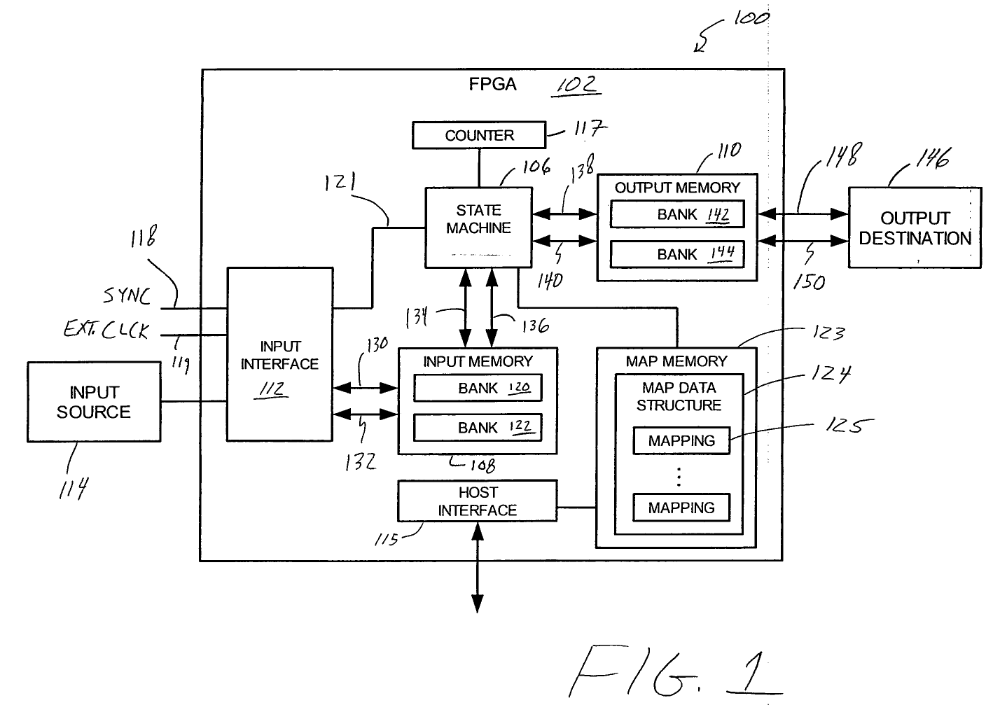

FIG. 1 is a block diagram of one embodiment of a switching matrix 100. In the embodiment shown in FIG. 1, the switching matrix 100 is implemented as a TDM switching matrix that switches 128 input channels onto 128 output channels. Each input channel corresponds to one of 128 time slots and includes 8 bits of data. Likewise, each output channel corresponds to one of 128 output time slots and includes 8 bits of data. The switching matrix 100, in this embodiment, supports mapping the 128 input channel received by the switching matrix 100 onto 128 output channels. The input channels multiplexed into input frames and the output channels are multiplexed into output frames using TDM. In general, the data included in each such input channel and output channel can include any type of data traffic—for example, traditional voice telephone traffic and/or data traffic (for example, in the form of internet protocol traffic). Although FIG. 1 shows a particular embodiment of a switching matrix 100, it is to be understood that other configurations are used in other embodiments. Indeed, one feature (which is described in more detail below) of the switching matrix 100 of FIG. 1 is that the design of the switching matrix 100 can be easily adjusted to different switching matrix configurations.

Switching matrix 100 is implemented using a field programmable gate array (FPGA) 102. The field programmable gate array 102 is implemented, in one embodiment, by specifying the functionality described here as being performed by the FPGA 102 in an appropriate hardware description language (HDL) such as the Very High Speed Integrated Circuit (VHSIC) Hardware Description Language (VHDL).

The field programmable gate array 102 includes an input interface 112, a state machine 106, an input memory 108, an output memory 110, and map memory 123. The input memory 108 includes two memory banks 120 and 122. Each of the banks 120 and 122 can store an entire input frame. In the embodiment shown in FIG. 1, the input memory 108 is implemented as a 1×2048 dual ported random access memory (also referred to here as a “DPR”) included in the FPGA 102. One of the banks of the input memory 108 is designated as a “write bank” into which an input frame is stored (as described below). After the input frame is written into the write bank, the write bank of the input memory 108 is designated as the “read bank” of the input memory 108 from which the input frame is read (as described below) and the other bank of the input memory 108 becomes the write bank for the next input frame.

Likewise, the output memory 110 includes two memory banks 142 and 144. Each of the banks 142 and 144 can store an entire output frame. In the embodiment shown in FIG. 1, the output memory 110 is implemented as a 1×512 dual ported random access memory included in the FPGA 102. One of the banks of the output memory 110 is designated as a “write bank” of the output memory 110 into which an output frame is written (as described below). After the output frame is written into the write bank of the output memory 110, the write bank of the output memory 110 is designated as the “read bank” of the output memory 110 from which the output frame is read (as described below) and the other bank of the output memory 110 becomes the write bank for the next output frame.

In the embodiment shown in FIG. 1, the input memory 108 and output memory 110 are implemented as a part of the FPGA 102. In an alternative embodiment, the input memory 108 and the output memory 110 are implemented using memory devices that are external to the FPGA 102.

The input interface 112 detects the beginning of, and receives, input frames from an input source 114. In the embodiment shown in FIG. 1, each input frame includes 1024 bits (that is, 128 eight-bit channels). For example, in one embodiment, the input source 114 is a TDM bus that is coupled to one or more devices that transmit one or more of the input channels contained in each input frame. The input interface 112 includes appropriate functionality to detect and receive input frames from the TDM bus. For example, in the embodiment shown in FIG. 1, the input interface 112 receives a frame synchronize signal 118 that is supplied to the input interface 112 to indicate that a new frame is being supplied from the input source 114 and an external clock signal 119 to synchronize the operations of the switching matrix 100 with the input source 114. In the embodiment shown in FIG. 1, the input interface 112 also generates an internal clock signal 121 that runs a frequency that is some multiplex of the external clock signal 119. For example, in one embodiment, the internal clock signal 121 runs at a frequency that is four times as fast as the external clock signal 119.

Input frames that are received by the switching matrix 100 are stored in the input memory 108. In the embodiment shown in FIG. 1, the input interface 112 writes each input frame received from the input source 114 into the write bank of the input memory 108. The write bank of the input memory 108 has a starting address that specifies the address in the input memory 108 at which that bank starts. In one implementation, the input frame 1024 is written to the write bank of the input memory 108 using multiple write operations, the first such write operation starting at the starting address of the write bank of the input memory 108 and the subsequent write operations occurring at successive addresses following the starting address (based on the size of the write operation supported by the input memory 108). The input interface 112 supplies the address for each write operation to the input memory 108 on input memory write address lines 130 and the data to be written on input memory write data lines 132. In one implementation of such an embodiment, a counter 117 is used to generate such addresses.

The FPGA 102 also includes map memory 123 in which a map data structure 124 is stored. By default, the switching matrix 100 maps the first input channel to the first output channel, the second input channel to the second output channel, etc. This default mapping is changed by specifying a mapping 125 stored in the map data structure 124. Each such mapping 125 is a data element (for example, a node in a linked list) that associates an output channel with data stored in the read bank of the input memory 108 that is to be read from the read bank and placed into that output channel. The mapping 125, more specifically, includes a pointer (or other reference) to an address in the read bank of the input memory 108 where the data for a particular input channel is stored. Such an approach makes the switching matrix 100 highly flexible. Such mappings 125 can be used to, for example, to multicast an input channel to multiple output channels using the switching matrix 100.

The switching matrix 100 also includes a host interface 115 that is used to couple the switching matrix to a control device (not shown in FIG. 1) such as a microprocessor that is used to store mappings 125 in the map data structure 124. A user of the switching matrix 100, in one embodiment, enters such mappings 125 stored in the map data structure 124 using, for example, craft software and/or an element or network management application. In one embodiment, the map data structure 124 is implemented using a linked list data structure. In other embodiments, the map data structure 124 is implemented in other ways. In one embodiment, the map memory 123 is implemented using multiple registers; in other embodiments, the map memory 123 is implemented in other ways.

In the embodiment shown in FIG. 1, the actual mapping of input channels to output channels is performed by state machine 106. The state machine 106 implements a state machine with suitable states and transition conditions to implement the functionality described here. Although the embodiment of a switching matrix 100 shown in FIG. 1 is implemented using a state machine, it is to be understood that such mapping functionality is implemented in other ways in other embodiments.

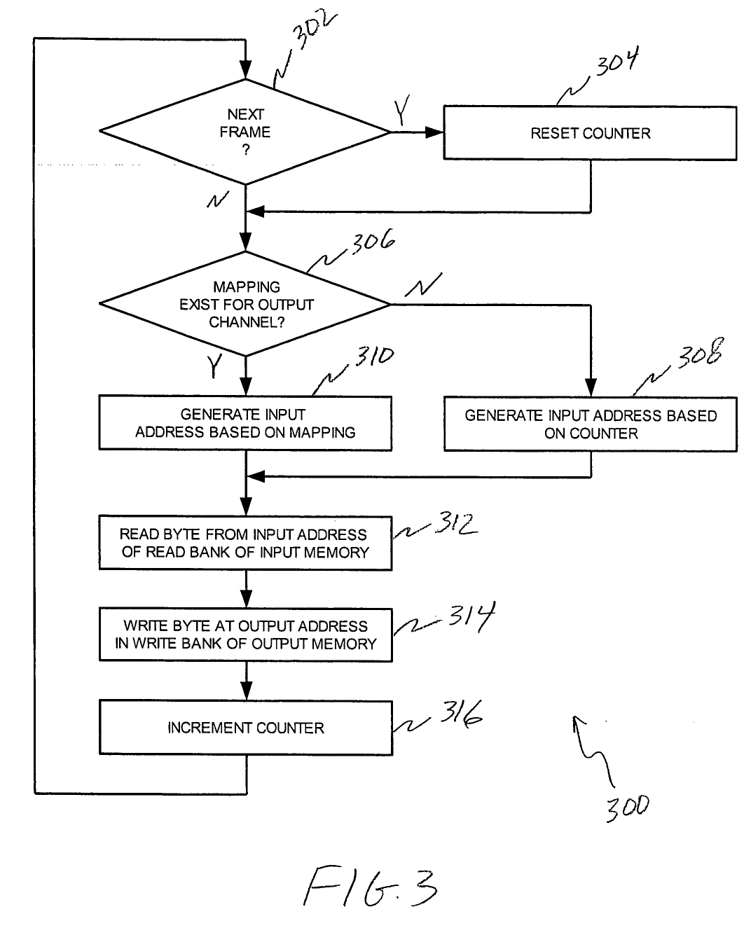

For each output channel in the output frame to be written to the write bank of the output memory 110, the state machine 106 determines which data stored in the read bank of the input memory 108 (for example, a particular input channel) is to be mapped to that output channel. Unless there is a mapping 125 stored in the map data structure 124 for that output channel, the state machine 106 maps the input channel having same channel number as the output channel. That is, the first input channel is mapped to the first output channel, the second input channel is mapped to the second output channel, etc. If there is a mapping 125 stored in the map data structure for that output channel, the state machine 106 determines which input channel is mapped to that output channel based on the mapping 125 stored in the map data structure 124. For example, in one embodiment the mapping 125 includes a pointer specifying an address in the read bank of the input memory 108 where data for input channel that should mapped to that output channel is stored. In other embodiments, the input channel that is to be mapped is specified in other ways. One approach to implementing the functionality of the state machine 106 is described below in connection with FIG. 3.

The state machine 106 supplies, to the input memory 108, the address of the data to be read from the read bank of the input memory 108 on input memory read address lines 134 and receives the data read from the read bank of the input memory 108 on input memory read data lines 136. The state machine 106 supplies, to the output memory 110, an address in the write bank of the output memory 110 on output memory write address lines 138 and supplies the data to be written to the write bank of the output memory 110 on output memory write data lines 140.

An output destination 146 reads an output frame stored in the read bank of the output memory 110. As used herein, “output destination” 146 refers to a device or component that reads the output frame from the output memory 110. For example, in one embodiment, the output destination 146 includes a G.SHDSL line interface module that reads the output frame from the read bank of the output memory 110 for processing and transmission along one or more G.SHDSL lines to one or more subscribers. Data is read from the read bank of the output memory 110 by supplying, to the output memory 110, an address on output memory read address lines 148 and receiving the data read from the read bank of the output memory 110 on output memory read lines 150.

Advantageously, the design of the embodiment of the switching matrix 100 shown in FIG. 1 by altering how the FPGA 102 is programmed. For example, in the event that it is desired that a new design of the switching matrix 100 support mapping 200 input channels onto 200 output channels, such a design change can be effectuated by altering how the FPGA is programmed. For example, the capacities of the memories (for example, the input memory 108, the output memory 110, and the map memory 123) used in the switching matrix 100 are increased by a suitable amount to support the new number of supported channels. Changing the design of the switching matrix 100 in this manner typically is relatively straightforward, which reduces the resources need to effectuate such a design change. This is especially the case where the switching matrix is designed to handle a large number of channels (for example, thousands of channels).

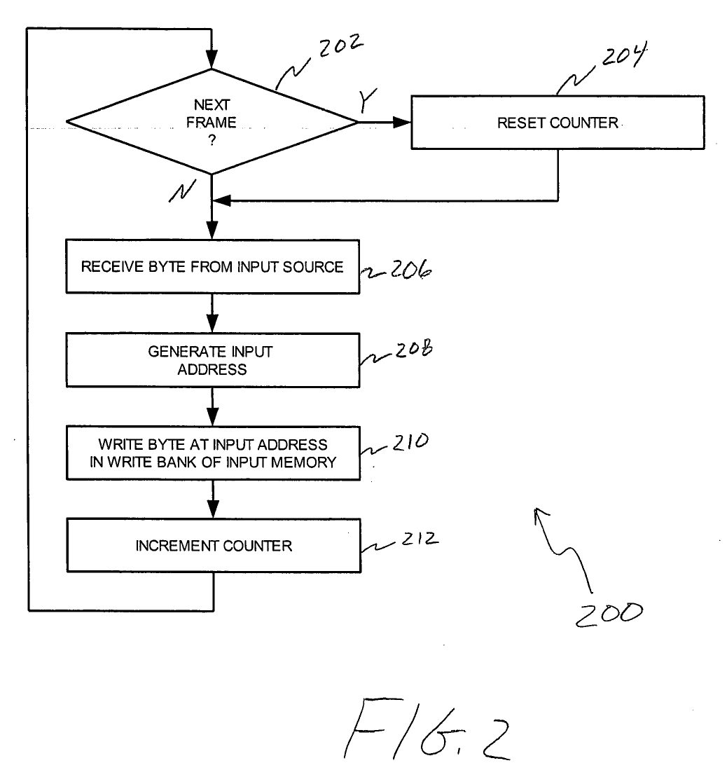

FIG. 2 is a flow diagram of one embodiment of a method 200 of clocking an input frame into the switching matrix 100 of FIG. 1. The embodiment of method 200 shown in FIG. 2 is described here as being implemented using the embodiment of a switching matrix 100 shown in FIG. 1. The functionality of method 200, in the embodiment shown in FIG. 2, is implemented using the input interface 112 of the switching matrix 100.

When the next input frame is ready to be processed (checked in block 202), a counter is reset (block 204). In one embodiment, the frame synchronization signal 118 is used to indicate when the next input frame is ready to be processed. The counter is used to generate successive addresses within the write bank of the input memory 108. For example, in one implementation, the counter is reset to zero.

A byte for the input frame is received from the input source 114 (block 206). Then, an address within the write bank of the input memory 108 is generated based on value of the counter (block 208). In the context of method 200, this address is referred to as the “input address.” In one implementation, the input address is determined by multiplying the value contained in the counter by 8 and adding the result to the starting address of the selected bank.

The received byte is then written to the write bank of the input memory 108 at the input address (block 210). Then, the counter is incremented (block 212). For example, in one embodiment, the counter is incremented by one. Each byte of the input frame is read from the input source 114 and written to the input memory 110 at successive addresses within the input memory 108 on successive clock cycles (looping back to block 202).

FIG. 3 is a flow diagram of one embodiment of method 300 of mapping input channels of an input frame to output channels of an output frame. The embodiment of method 200 shown in FIG. 2 is described here as being implemented using the embodiment of a switching matrix 100 shown in FIG. 1. The functionality of method 300, in such an embodiment, is implemented by the state machine 106 of the FPGA 102. A state machine having suitable states and state transition conditions is used in such an embodiment.

When the next input frame is ready to be processed (checked in block 302), a counter is reset (block 304). In one embodiment, the frame synchronization signal 118 is used to indicate when the next input frame is ready to be processed. The counter is used to identify what output channel is currently being processed (also referred to here as the “current output channel”). For example, in one implementation, the counter is reset to zero. In one implementation of such an embodiment, the same counter is used by both method 200 and method 300 and is reset when the frame synchronization signal 118 indicates that a new frame is available from the input source 114 (that is, when the frame synchronization signal is asserted). The counter is also used to generate successive addresses within one of the banks 142 or 144 of the output memory 110 at which data for the current output channel is to be written.

For the current output channel, the input channel that is mapped to the output channel is determined (referred to here as the “mapped input channel”). In the embodiment shown in FIG. 3, this is done by determining the address within the read bank of the input memory 108 at which the mapped input channel is stored. This address is referred to here as the “input address.” The map data structure 124 is consulted to determine if a mapping 125 is stored in the map data structure 124 for the current output channel (checked in block 306). If a mapping 125 does not exist in the map data structure 124 for the current output channel, the input address is calculated based on the value contained in the counter (block 308). For example, in one implementation of such an embodiment, the input address is calculated by multiplexing the value stored in the counter by eight and adding result to the starting address of the read bank of the input memory 108.

If there is a mapping 125 in the map data structure 124 for the current output channel, the input address is generated based on address data stored in the map data structure 124 for the current output channel (block 310). For example, in one embodiment, the address stored in the map data structure 124 for the current output channel is added to the starting address of the read bank of input memory 108 in order to generate the input address.

Then, the byte stored in the read bank of the input memory 108 at the input address is read (block 312). The input address is supplied to the input memory 108 on the input memory read address lines 134 and the byte read from the input memory 108 is received on the input memory read data lines 136. The read byte is written to the write bank of the output memory 110 at an address generated from the counter (block 314). The address within the write bank of the output memory 110 at which the read byte is written is referred to here as the “output address.” In one embodiment, the output address is generated by adding the value of stored in the counter to the starting address of the write bank of the output memory 110. Then, the counter is incremented (block 316). For example, in one embodiment, the counter is incremented by one. Each output channel of the output frame is processed on successive clock cycles (looping back to block 302).

A number of embodiments of the invention defined by the following claims have been described. Nevertheless, it will be understood that various modifications to the described embodiments may be made without departing from the spirit and scope of the claimed invention. Accordingly, other embodiments are within the scope of the following claims.

1. A switching matrix comprising:
a field programmable gate array having an input memory and an output memory; and
wherein the field programmable gate array stores in the input memory an input frame having a plurality of input channels; and
wherein the field programmable gate array stores in the output memory an output frame having a plurality of output channels is stored;
wherein the field programmable gate array further includes a map memory in which the field programmable gate array stores at least one mapping that specifies one of the plurality of input channels that is mapped to one of the output channels.

2. The switching matrix of claim 1, wherein each of the input channels corresponds to one of a plurality of time slots.

3. The switching matrix of claim 1, wherein each of the output channels corresponds to one of a plurality of time slots.

4. The switching matrix of claim 1, wherein the input memory includes a plurality of banks of memory in which a plurality of input frames are stored by the field programmable gate array.

5. The switching matrix of claim 1, wherein the input memory includes a plurality of banks of memory in which a plurality of input frames are stored by the field programmable gate array.

6. The switching matrix of claim 1, wherein the field programmable gate array includes a logic block that includes an input interface, wherein the input interface stores the input frame in the input memory.

7. The switching matrix of claim 1, wherein the field programmable gate array includes a state machine block, wherein the state machine block reads one of the plurality of input channels of the input frame stored in the input memory and writes the input channel to one of the plurality output channels of the output frame stored in the output memory.

8. The switching matrix of claim 7, wherein the state machine block reads the mapping from the map memory.

9. The switching matrix of claim 1, wherein the input memory includes a dual ported random access memory.

10. The switching matrix of claim 1, wherein the output memory includes a dual ported random access memory.

11. A switching matrix comprising:
means for storing an input frame having a plurality of input channels;
means for storing an output frame having a plurality of output channels; and
means for mapping at least one of the input channels of the input frame to a corresponding one of the plurality of output channels of the output frame.

12. The switching matrix of claim 11, wherein the means for mapping includes:
means for reading the at least one of the input channels of the input frame from the means for storing the input frame; and
means for writing to the means for storing the output frame the at least one of the input channels of the input frame in the corresponding one of the plurality of channels of the output frame.

13. A switching matrix comprising:
an input memory;
an output memory; and
a field programmable gate array that stores in the input memory an input frame having a plurality of input channels and that stores in the output memory an output frame having a plurality of output channels; and
wherein the field programmable gate array includes a map memory in which the field programmable gate array stores at least one mapping that specifies one of the plurality of input channels that is mapped to one of the output channels.

14. The switching matrix of claim 13, wherein the input memory is included in the field programmable gate array.

15. The switching matrix of claim 13, wherein the output memory is included in the field programmable gate array.

16. The switching matrix of claim 13, wherein the field programmable gate array receives each of the plurality of input channels from an input source and stores each of the plurality input channels in the input memory.

17. The switching matrix of claim 16, wherein the field programmable gate array reads one of the plurality of input channels stored in the input memory and writes the input channel to one of the plurality output channels of the output frame stored in the output memory.

18. The switching matrix of claim 13, wherein each of the input channels corresponds to one of a plurality of time slots and each of the output channels corresponds to one of a plurality of time slots.

19. The switching matrix of claim 13, wherein the input memory includes a plurality of banks of memory in which a plurality of input frames are stored by the field programmable gate array and the input memory includes a plurality of banks of memory in which a plurality of input frames are stored by the field programmable gate array.

20. The switching matrix of claim 13, wherein the input memory includes a dual ported random access memory and the output memory includes a dual ported random access memory.
